(19) United States
(12) Patent Application Publication
(10) Pub. No.: US 2004/0232476 A1
(43) Pub. Date: Nov. 25, 2004

(54) EEPROM cell structures having non-uniform channel-dielectric thickness and methods of making the same

(76) Inventors: Sung-Taeg Kang, Seoul (KR); Seung Beom Yoon, Suwon (KR); Jeong Uk Han, Suwon (KR); Sung Woo Park, Gunpo (KR)

Correspondence Address: HARNESS, DICKEY & PIERCE, P.L.C., P.O. BOX 8910, RESTON, VA, 20195, US

(21) Appl. No.: 10/834,226

(22) Filed: Apr. 29, 2004

(30) Foreign Application Priority Data
May 20, 2003 (KR) 2003-31910
Sep. 1, 2003 (KR) 2003-60763

(51) Int. Cl. H01L 29/788

(52) U.S. Cl. 257/315

(57) ABSTRACT

An EEPROM cell structure, having varied gate-dielectric thickness, can include: a semiconductor substrate; a memory transistor and a select transistor on the substrate; and a floating junction formed in the substrate between the transistors and extending partially underneath the memory transistor; a gate-dielectric layer in the memory transistor, along a lateral direction, being arranged into a tunnel region having thickness Tₜᵤₙₙₑₗ and overlying a portion of the floating junction, a near-channel region having thickness Tₙₑₐᵣ>Tₜᵤₙₙₑₗ and located at a side of the tunnel region opposite the select transistor, and a far-channel region having thickness T_{far}<Tₙₑₐᵣ and located at a side of the near-channel-region opposite the tunnel-region. A related method making such an EEPROM cell structure has corresponding steps.

### BACKGROUND OF THE PRESENT INVENTION

Electrically erasable programmable read-only memories (EEPROMs) are known. FIG. 1 is a cross-section of a typical EEPROM cell structure 100 including a memory transistor (MTR) 140 and a corresponding select transistor 142 on a substrate 101, according to the Background Art. MTR 140 includes a gate-dielectric structure 156 that includes a gate-dielectric part 104a and 104z, having thicknesses T₁₀₄ₐ and T_{104z}, where T_{104z}>T₁₀₄ₐ.

Charging/discharging floating gate 116a of MTR 140 increases/decreases the threshold voltage (Vth) of MTR 140 relative to a nominal value. In EEPROM cell structure 100, a logical zero/one value is represented by an increased/decreased Vth

$$( {V}_{th}^{decreased} , {V}_{th}^{increased} )$$

or vice-versa. The logical value stored in MTR 100 is reflected by whether or not a predetermined read voltage (Vr) is of sufficient magnitude to turn-on MTR 100.

Like other integrated circuits, an ongoing design goal is to more highly integrate the EEPROM, specifically by reducing the size of the cell structure. As channel length L has decreased, MTR 140 has exhibited short-channel effects, which are undesirable. The Background Art has compensated by forming a punch-through-prevention (PTP) region 149 of higher dopant (e.g., P-type) concentration (P+) relative to the lower dopant concentration (P−) of substrate 101.

### SUMMARY OF THE PRESENT INVENTION

One of the embodiments of the present invention is directed to an EEPROM cell structure having varied gate-dielectric thickness. Such an EEPROM cell structure may include: a semiconductor substrate; a memory transistor and a select transistor on the substrate; and a floating junction formed in the substrate between the transistors and extending partially underneath the memory transistor; a gate-dielectric layer in the memory transistor, along a lateral direction, being arranged into a tunnel region having thickness Tₜᵤₙₙₑₗ and overlying a portion of the floating junction, a near-channel region having thickness Tₙₑₐᵣ>Tₜᵤₙₙₑₗ and located at a side of the tunnel region opposite the select transistor, and a far-channel region having thickness T_{far}<Tₙₑₐᵣ and located at a side of the near-channel-region opposite the tunnel-region.

Another of the embodiments of the present invention is directed to a method of making an EEPROM cell structure having varied gate-dielectric thickness. Such a method may include: forming a gate-dielectric first layer on a semiconductor substrate having first, second and third areas corresponding later in manufacture to tunnel, far-channel and near-channel regions, respectively, the first and third areas being separated by the second area; selectively removing portions of the first layer over the first and third areas; forming a gate-dielectric second layer on the first layer and exposed portions of the substrate; thicknesses Tₜᵤₙₙₑₗ, Tₙₑₐᵣ, T_{far} of gate-dielectric material over the first, second and third areas, respectively, having the relationships Tₙₑₐᵣ>Tₜᵤₙₙₑₗ and Tₙₑₐᵣ>T_{far}; forming successively, on the second layer, additional layers corresponding to components of a transistor; and selectively removing portions of the first, second and additional layers to define inchoate memory and select transistors such that the first, second and third areas are located below the memory transistor.

Additional features and advantages of the present invention will be more fully apparent from the following detailed description of example embodiments and the accompanying drawings.

### BRIEF DESCRIPTION OF THE DRAWINGS

FIG. 1 is a cross-section of an electrically-erasable programmable read-only (EEPROM) cell structure according to the Background Art.

The other drawings are: intended to depict example embodiments of the present invention and should not be interpreted to limit the scope thereof.

FIG. 2 is a cross-section of an EEPROM cell structure according to an embodiment of the present invention.

FIG. 3 is a simplified version of FIG. 2 showing a superimposed circuit representation.

FIG. 4 is a version of FIG. 2 that calls out thicknesses and lengths of selected components.

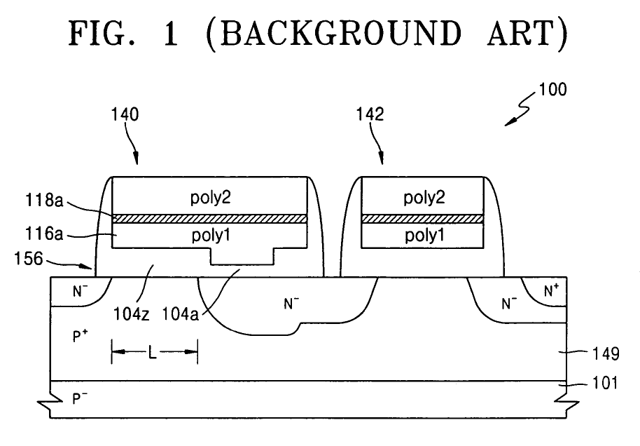

And, FIGS. 5A-5H are cross-sections of various stages in the manufacture of EEPROM cell structures according to embodiments of the present invention.

### DETAILED DESCRIPTION OF EXAMPLE EMBODIMENTS

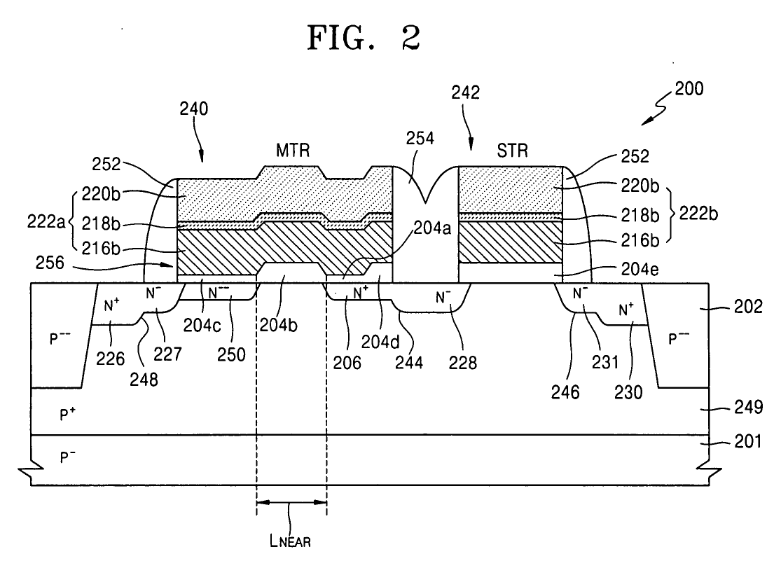

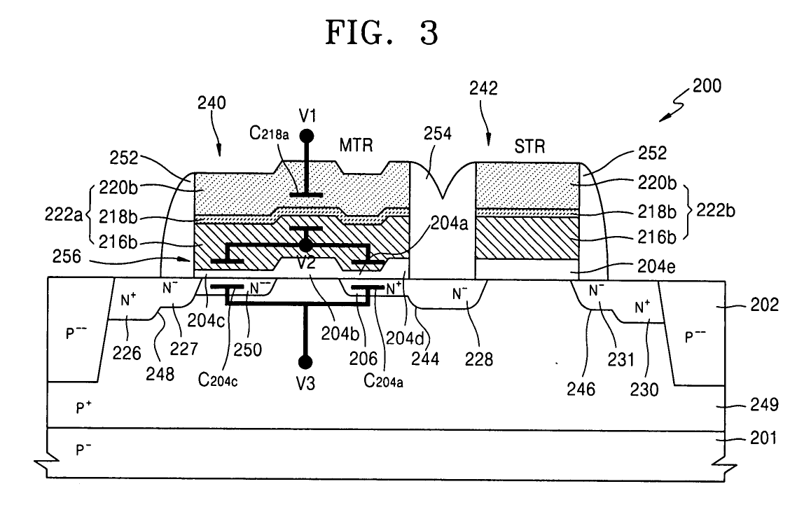

FIG. 2 is a cross-section of an electrically-erasable programmable read-only (EEPROM) cell structure 200 according to an embodiment of the present invention. The EEPROM cell structure 200 includes a memory transistor (MTR) 240 and a corresponding select transistor (STR) 242 formed on a semiconductor, e.g., polysilicon, substrate 201. MTR 240 and STR 242 are, e.g., FETs such as MOSFETs. As an example that will be carried through the remainder of the discussion, substrate 201 can be doped with P-type dopant; alternatively, N-type dopant can be used.

Substrate 201 has regions formed within it including: field regions 202; drain/source (D/S) region 246 associated with STR 242; D/S region 248 associated with MTR 240; a punch through prevention (PTP) region 249 of a greater concentration (e.g., P+, in terms of the example introduced above) of P-type-dopant relative to substrate 101 of lesser concentration (P−) of P-type dopant; and a floating junction 244 located between MTR 240 and STR 242 and extending partially underneath MTR 240. Floating junction 244 is a double-doped drain (DDD) having zone 228 of a lesser concentration (e.g., N−, in terms of the example introduced above) of N-type dopant relative to zone 206 of greater concentration (N+) of N-type dopant. Zone 206 is the part of floating junction 244 that extends underneath MTR 240, while zone 228 lies generally in the area between MTR 240 and STR 242. D/S regions 246 and 248 have a lightly-doped-drain (LDD) configuration respectively includes zones 231 and 227 of lesser dopant concentration (e.g., N−, in terms of the example introduced earlier) located above adjacent MTR 240 and SR 242; and zones 230 and 226 of greater dopant concentration N+ located adjacent field regions 202.

Substrate 201 also can have optional compensation region 250 which occupies a part of the channel region of MTR 240 adjacent to zone 227 of D/S 248. The presence or absence of compensation region 250 represents different embodiments according to the present invention. Compensation region is of lesser dopant concentration (e.g., N−−, in terms of the example introduced above) than zone 227 of D/S 248.

MTR 240 and STR 242 each have a dual-gate (floating gate and control gate) architecture. MTR 240 includes the following: a gate dielectric, e.g., an oxide of silicon, structure 256 having parts 204a, 204b, 204c and 204d; a floating gate layer 216a, e.g., formed of polysilicon; a dielectric structure 218a, e.g., an oxide-nitride-oxide (ONO) structure; and a control gate layer 220a, e.g., formed of polysilicon. It is noted that gate-dielectric parts 204b and 204c together correspond to Background Art gate-dielectric part 104z. Taken together, gate-dielectric parts 204b and 204c represent a non-uniform thickness of gate-dielectric material, while in contrast thickness T_{104z} of Background Art gate-dielectric part 104z is uniform.

Gate-dielectric part 204a is located over zone 206 of floating junction 244, and corresponds to the tunnel region of MTR 240 through which charging/discharging via Fowler-Nordheim (F-N) tunneling primarily takes place. F-N tunneling is the principal mechanism by which floating gate 216a is charged/discharged in order to increase/decrease Vth. Gate-dielectric parts 204b and 204c are located over the channel region in substrate 201. Also, gate-dielectric parts 204b and 204c can be described as near-channel and far-channel parts because they are relatively closer to and further from, respectively, both the tunneling region and gate-dielectric part 204a. Gate-dielectric part 204e is located: (also) over zone 206; at a side of gate-dielectric part 204a opposite gate-dielectric part 204b; and between gate-dielectric part 204a and STR 242.

Thicknesses Tₙₑₐᵣ and T_{edge} of gate-dielectric parts 204b and 204dshould be significantly thicker than a thickness Tₜᵤₙₙₑₗ, namely Tₙₑₐᵣ>Tₜᵤₙₙₑₗ and T_{edge}>Tₜᵤₙₙₑₗ respectively, in order to constrain the area through which tunneling takes place. Also, thickness T_{far}, should be significantly less than Tₙₑₐᵣ, namely T_{far}<Tₙₑₐᵣ. Thickness Tₜᵤₙₙₑₗ of gate-dielectric part 204a can approximately equal thickness T_{far}, of gate-dielectric part 204c, Tₜᵤₙₙₑₗ≈T_{far}. A thickness T_{edge} of gate-dielectric part 214d and a thickness T_{STR} of gate-dielectric structure 204e each can approximately equal thickness Tₙₑₐᵣ, namely T_{edge}≈Tₙₑₐᵣ and T_{STR}≈Tₙₑₐᵣ, for manufacturing efficiency. Moreover, a ratio of thicknesses

$$( \frac{{T}_{near}}{{T}_{tunnel}} )$$

can be in the range

$$1 < \frac{{T}_{near}}{{T}_{tunnel}} < ( \approx 4 ) .$$

And a ratio of thicknesses

$$( \frac{{T}_{near}}{{T}_{far}} )$$

can be in the range

$$1 < \frac{{T}_{near}}{{T}_{far}} < ( \approx 4 ) .$$

A lateral dimension of the near-channel region, Lₙₑₐᵣ, should be Lₙₑₐᵣ≧0.1 μm to constrain tunneling to region corresponding to gate-dielectric part 204a. The same is true for the length of the edge region corresponding to gate-dielectric part 204d.

STR 242 correspondingly 204e; a floating gate layer 216b, e.g., formed of polysilicon; a dielectric structure 218b, e.g., an ONO structure; and a control gate layer 220b, e.g., formed of polysilicon. Relative to gate-dielectric structures 256 and 204e, item nos. 216a/b-220a/b can be described as representing other components typically found in an FET and, for brevity, can be grouped together as additional layers 222a/b, respectively.

Cell structure 100 also includes: sidewall spacers 252 located above zones 231 and 227, respectively; and sidewall spacer 254 corresponding to spacers such as spacers 252 that became conjoined during formation.

In developing the present invention, the following problem with the Background Art was recognized and the physics thereof was determined. Prior to using PIT region 149, a read-voltage Vr of 1.8 volts was typically applied to EEPROM cell structure 100. Use of PTP region 149 according to the Background Art uniformly up-shifts/increases both

$${V}_{th}^{decreased} \text{and} {V}_{th}^{increased}$$

by an amount ΔV_{PTP}. Consequently the typical distribution

$$\{ {( {V}_{th}^{decreased} + Δ {V}_{PTP} )}_{i} \}$$

of

$${( {V}_{th}^{decreased} + Δ {V}_{PTP} )}_{i}$$

values now includes an upper range

$$\{ {V}_{th ( i )}^{decreased ( + )} \}$$

that has values greater than Vr. An instance of MTR 140 having Vᵥₕ^{decreased(+)} will always be interpreted as storing the same logical value regardless of the logical value actually being stored because

$${V}_{th}^{decreased ( + )} > {V}_{r} ,$$

which is a problem. A simplistic solution to that problem would be to compensate by correspondingly up-shifting/increasing Vr by ΔV_{PTP},

$${V}_{r}^{simplistic} = {V}_{r} + Δ {V}_{PTP} .$$

But this simplistic compensation also correspondingly increases power consumption, which also is a problem. Where EEPROM cell structure 100 is used in a low power-consumption device, e.g., a small, battery-powered device such as a Smart Card,

$${V}_{r}^{simplistic}$$

is especially undesirable. Instead, technology is needed by which

$${V}_{th}^{PTP} = {V}_{th}^{pre \text{-} PTP} + Δ {V}_{PTP}$$

can be decreased as compensation for the PTP-induced threshold voltage increase. Among other things, embodiments according to the present invention exhibit a uniform down-shift/decrease in Vth

$$Δ {V}_{\begin{matrix}non \text{-} uni \\ channel \text{-} dielec\end{matrix}} \approx - Δ {V}_{PTP}$$

that achieves the following,

$$\begin{matrix}{V}_{th}^{comp} = {V}_{th}^{PTP} + Δ {V}_{\begin{matrix}non \text{-} uni \\ channel \text{-} dielec\end{matrix}} \\ = ( {V}_{th}^{pre \text{-} PTP} + Δ {V}_{halo} ) + ( - Δ {V}_{halo} ) \\ {V}_{th}^{comp} \approx {V}_{th}^{pre \text{-} PTP}\end{matrix} \qquad \text{(Eq. No. 1)}$$

where

$$Δ {V}_{\begin{matrix}non \text{-} uni \\ channel \text{-} dielec\end{matrix}}$$

represents a uniform down-shift/decrease in Vth due to non-uniform thickness of gate-dielectric material over the channel region of the memory transistor (to be discussed in more detail below).

Such a decreased or compensated Vth, namely

$${V}_{th}^{comp} ,$$

according to an aspect of the present invention, is explained as follows. Gate-dielectric structure 256 of MTR 240 is formed such that gate-dielectric parts 204b and 204c together represent a non-uniform thickness of gate-dielectric material over the channel. The degree of non-uniformity is significantly greater than would result from manufacturing-tolerance associated with the manufacture of a uniform-thickness layer. Such non-uniform thickness of gate-dielectric material over the channel represented by gate-dielectric parts 204band 204ctaken together achieves a uniform down-shift/decrease in VTₜₕ^{PTP} by

$$Δ {V}_{\begin{matrix}non \text{-} uni \\ channel \text{-} dielec\end{matrix}} = - Δ {V}_{PTP} .$$

In more detail, MTR 240 can be represented by the following circuit,

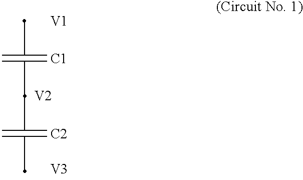

which has series-connected capacitors C1=C₂₁₈ₐ and C2=C₂₅₆ (with C2 connected to zero volts). During charging, V1 is a high voltage (V_{H}), V1=V_{H} and is applied to control gate layer 220 a while V3 is zero volts, V3=O^{v}, and is applied to floating junction 244. Conversely, during discharging, V1=O^{v} is applied to control gate layer 220 while V3=V_{H} is applied to floating junction 244. Voltage V1 divides across capacitors C1 and C2 to yield V2 as follows

$$V2 = V1 ( \frac{{C}_{dielec\_nearest {\_v}_{H}}}{{C}_{218 a} + {C}_{256}} ) \qquad \text{(Eq. No. 2)}$$

where

$$\frac{{C}_{dielec\_nearest {\_v}_{H}}}{{C}_{218 a} + {C}_{256}}$$

is the capacitive coupling ratio and C_{dilelec}_{_{—}}ₙₑₐᵣₑₛₜ_{_{—}}_{V}_{_{H}} is the capacitance of the capacitor nearest to the node to which V_{H} is applied. It is noted that V2 is directly proportional to how strongly MRT 240 is charged/discharged.

It is also noted that C₂₅₆=C_{204c}+C_{204b}+C₂₀₄ₐ+C_{204d}. Correspondingly, the circuit No. 1 can be redrawn as follows,

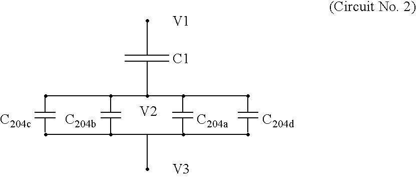

in which capacitors C_{204c}, C_{204b}, C₂₀₄ₐ and C_{204d} are connected in parallel to each other and series connected to capacitor C₂₁₈ₐ. Substituting for C₂₅₆ in Eq. No. 2 results in the following. Voltage V2 divides across capacitors C1 and C2 to yield V2 as follows.

$$V2 = V1 ( \frac{{C}_{dielec\_adjacent {\_v}_{H}}}{{C}_{218 a} + {C}_{204 c} + {C}_{204 b} + {C}_{204 a} + {C}_{204 d}} ) \qquad \text{(Eq. No. 3)}$$

Capacitances C_{204b} and C_{204d} of gate-dielectric parts 204b and 204d are much smaller than the capacitances C₂₀₄ₐ and C_{204c} of gate-dielectric parts 204a and 204c, respectively. So circuit No. 2 can be redrawn yet again as follows.

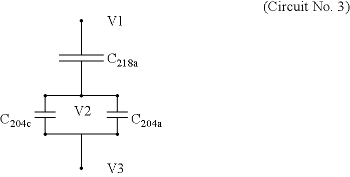

FIG. 3 is a simplified version of FIG. 2 showing circuit No. 3 superimposed upon MTR 240. In terms of Eq. No. 3, capacitances C_{204b} and C_{204d} are negligible and drop out of the equation, as indicated below.

$$V2 = V1 ( \frac{{C}_{dielec\_adjacent {\_v}_{H}}}{{C}_{218 a} + {C}_{204 c} + {C}_{204 a}} ) \qquad \text{(Eq. No. 4)}$$

Eq. No. 5 facilitates explanation of the uniform down-shift/decrease in Vth, e.g., as compensation for

$${V}_{th}^{PTP} ,$$

according to embodiments of the present invention. Again, during charging, V1=V_{H} and is applied to control gate layer 220a while V3=O^{v} and is applied to floating junction 244, so C_{dielec}_{_{—}}_{adjacent}_{_{—}}_{V}_{H}=C₂₁₈ₐ. Substituting into Eq. No. 4 gives the following equation.

$${V2}^{charge} = {V}_{H} ( \frac{{C}_{218 a}}{{C}_{218 a} + {C}_{204 c} + {C}_{204 a}} ) \qquad \text{(Eq. No. 5)}$$

Again, during discharging, V1=O^{v} and is applied to control gate layer 220a, while V3=V_{H} and is applied to floating junction 244, plus C_{dielec}_{_{—}}_{adjacent}_{_{—}}_{V}_{H}=C₂₀₄ₐ. Substituting into Eq. No. 4 gives the following equation.

$${V2}^{discharge} = {V}_{H} ( \frac{{C}_{204 a}}{{C}_{218 a} + {C}_{204 c} + {C}_{204 a}} ) \qquad \text{(Eq. No. 6)}$$

Inspection of Eq. Nos. 5 and 6 reveals that

$${V2}^{charge} ∝ \frac{1}{{C}_{218 a} + {C}_{204 c} + {C}_{204 a}} \text{and}$$

$${V2}^{discharge} ∝ \frac{1}{{C}_{218 a} + {C}_{204 c} + {C}_{204 a}} ,$$

can be generalized as follows.

$${V2}^{MTR\_ 240} ∝ \frac{1}{{C}_{218 a} + {C}_{204 c} + {C}_{204 a}} \qquad \text{(Eq. No. 7)}$$

In contrast, the proportionality for V2 according to Background Art 140 is as follows.

$${V2}^{MTR\_ 140} ∝ \frac{1}{{C}_{118 a} + {C}_{104 a}} \qquad \text{(Eq. No. 7)}$$

The non-uniformity represented by gate-dielectric parts 204c and 204b, taken together, according to embodiments of the present invention introduces an extra term into the denominator of the V2 proportionality, namely C_{204c}.

In other words, according to embodiments of the present invention, the proportionality

$${V2}^{MTR\_ 240} ∝ \frac{1}{{C}_{204 c}} \qquad \text{(Eq. No. 8)}$$

exists, as contrasted to the Background Art for which no there is no term in the V2^{MTR}_{^{—}}¹³⁰ proportionality corresponding to C_{204c}. As such, gate-dielectric part 204c can be used to down-shift/decrease Vth.

Recalling that capacitance is inversely proportional to thickness,

$$C ∝ \frac{1}{\text{thickness}} , \qquad \text{(Eq. No. 9)}$$

capacitance C_{204c} can be increased by decreasing T_{far} to be less than Tₜᵤₙₙₑₗ, namely T_{far}<Tₜᵤₙₙₑₗ. Increasing 204c reduces V2^{MTR}_{^{—140}} relative to Background Art V2^{MTR}_{^{—}}¹⁴⁰.

The non-uniform thickness of gate-dielectric material represented by gate-dielectric parts 204b and 204c taken together (according to embodiments of the present invention) results in smaller V2 values as contrasted with the Background Art, V2^{MTR}_{^{—}}²⁴⁰<V2^{MTR}_{^{—}}¹⁴⁰, which causes MTR 240 to charge less strongly as contrasted to Background Art MTR 140. Such weaker charging results in a relatively reduced Vth. Also, the non-uniformity represented by gate-dielectric parts 204b and 204c taken together (according to embodiments of the present invention) causes MTR 240 to discharge more strongly as contrasted with Background Art MTR 140. Such stronger discharging also results in relatively reduced Vth. Hence, the net effect of the non-uniformity represented by gate-dielectric parts 204b and 204c taken together achieves a uniform down-shift/decrease in Vₜₕ^{PTPp} by

$${ΔV}_{\begin{matrix}non - uni \\ gate - dielec\end{matrix}} \approx - {ΔV}_{PTP} .$$

In other words, the undesirable increase in Vth due to use of a PTP region is compensated for by the net effect of the non-uniformity represented by gate-dielectric parts 204b and 204c taken together.

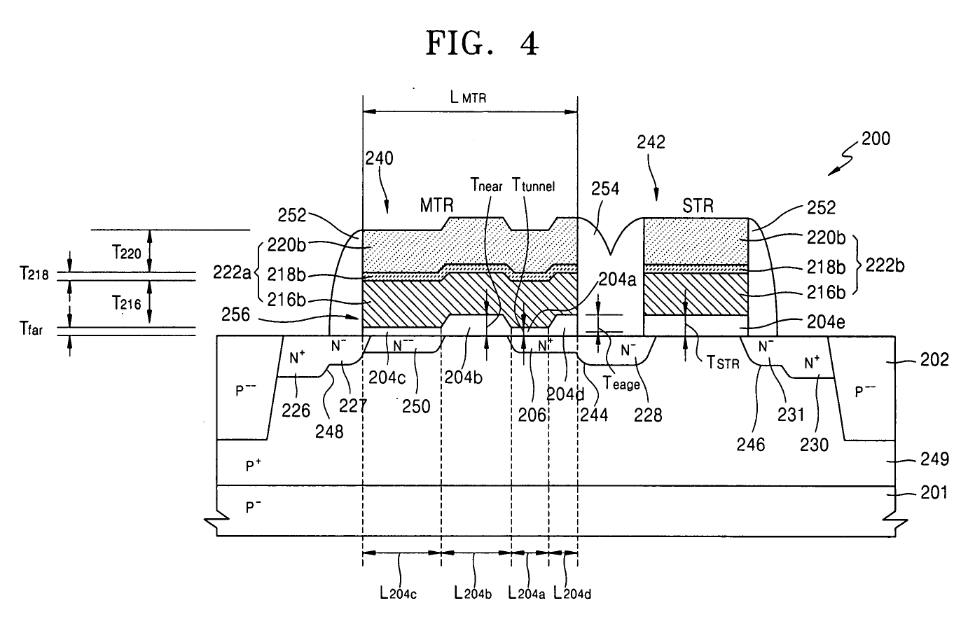

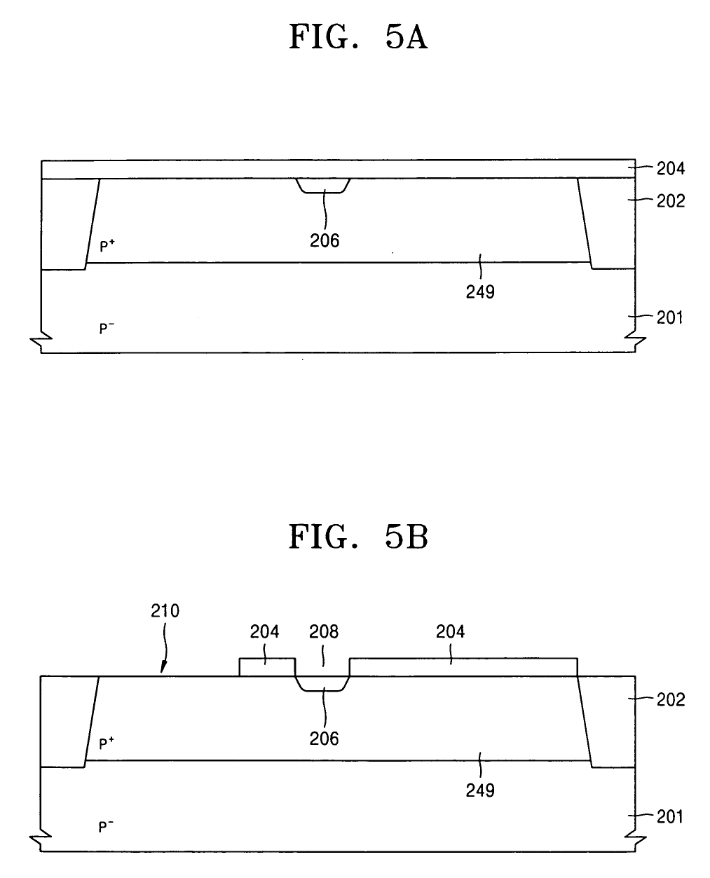

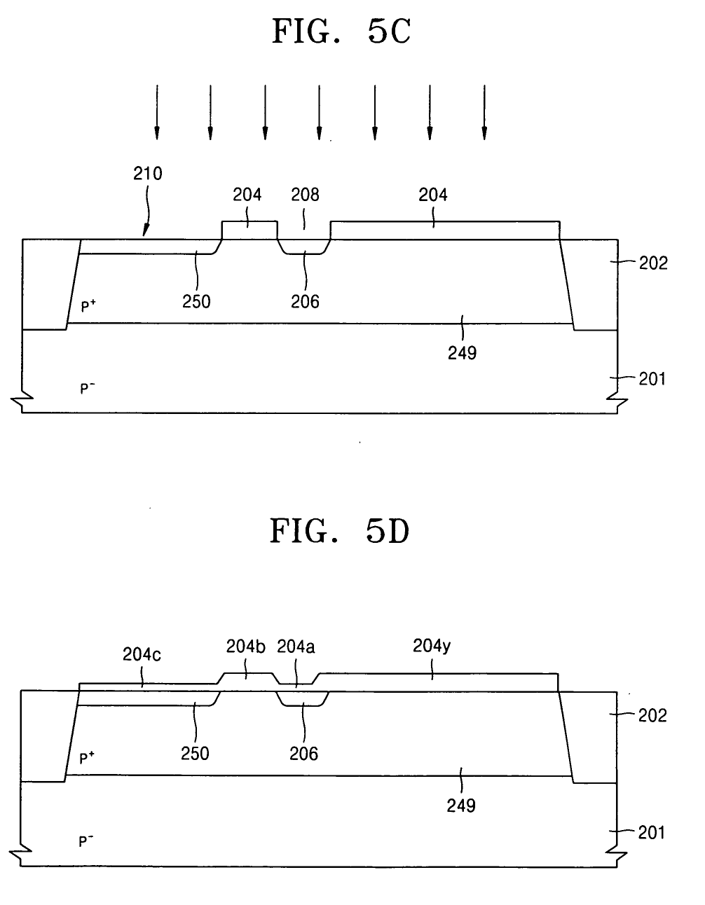

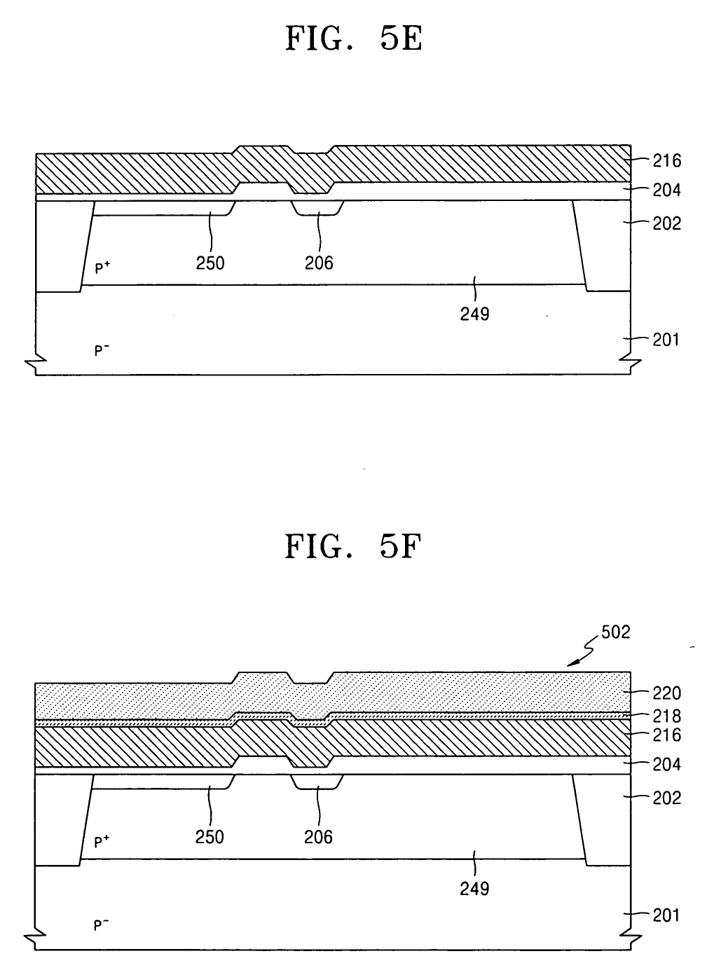

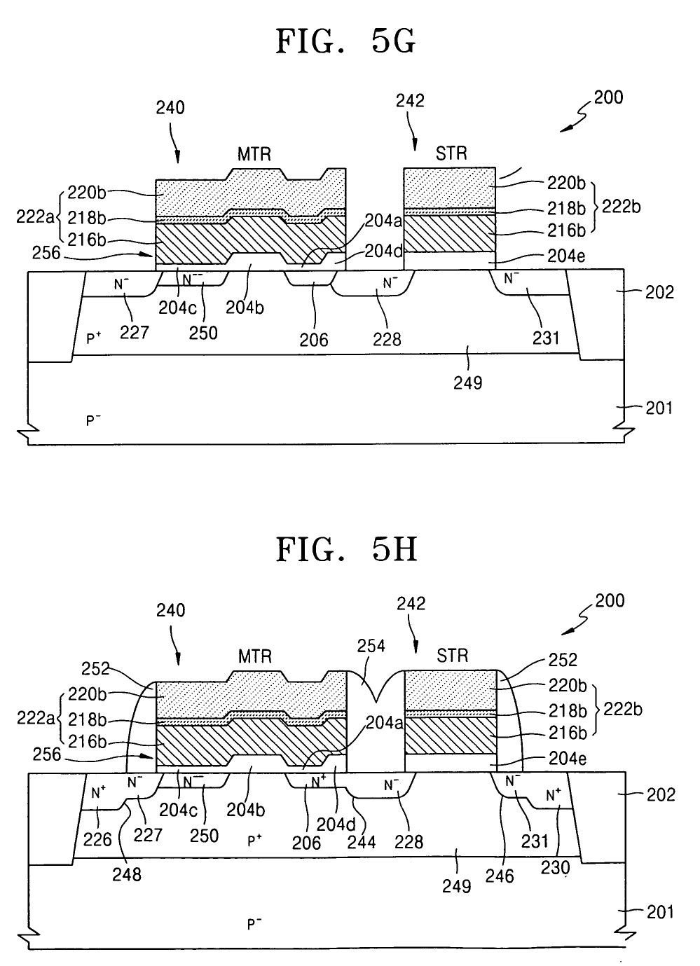

The example introduced above will now be extended with approximate (albeit example) values for some of the parameters of EEPROM cell structure 200, as shown in the following table. FIG. 4 is a version of FIG. 2 that shows the thicknesses and lengths that the extended-example mentions below. Length L_{MTR} is the length of MTR 240. Lengths of the gate-dielectric parts 204a-204d are Lₐ, L_{b}, L_{c}, and L_{d}, respectively.

| Param. | Approx. Value |
|---|---|
| Lₐ | 0.18 ≦ Lₐ ≦ 0.20 μm |
| L_{b} | ≧0.10 μm |
| L_{c} | =0.43 μm |
| L_{d} | =0.12 μm |
| L_{MTR} | =0.9 μm |
| Tₜᵤₙₙₑₗ | =70 Å |
| Tₙₑₐᵣ | 250 Å ≦ T_{edge} ≦ 280 Å |
| T_{far} | =70 Å |
| T_{edge} | 250 Å ≦ T_{edge} ≦ 280 Å |
| T_{STR} | 250 Å ≦ T_{edge} ≦ 280 Å |
| T₂₁₆ | 0.15 μm |
| T₂₁₈ | =90 Å |
| T₂₂₀ | 0.15 μm |

Again, the specific values of lengths and thicknesses in the above table are merely examples and are not limiting.

Examples of methods for making embodiments of the present invention will now be discussed, in terms of the example introduced earlier, and relative to FIGS. 5A-5H, which are cross-sections of various stages in the manufacture of EEPROM cell structure 200 according to embodiments of the present invention. In FIG. 5A, substrate 201 of P-type conductivity is provided. PTP region 249 is formed by ion implantation, e.g., of Boron at 700 Kev & 2.0(10¹³)/cm², as well as at 50 Kev & 1.5(10¹²)/cm². Next, field regions 202 are formed. A gate-dielectric first layer 204 is formed to a thickness of about 240˜280 Å. Then more ion implantation is performed to produce zone 206 of N-type impurity, e.g., using Phosphorous at 50-70 Kev & 7.0(10¹³)˜1.0(10¹⁴)/cm² or Arsenic at 60-120 Kev & 7.0(10¹³)˜1.5(10¹⁴)/cm².

In FIG. 5B first layer 204 is patterned, and then portions located over areas 208 and 210 corresponding later in manufacture to the tunnel region and the far-channel region, respectively, are removed.

In FIG. 5C, more ion implantation is optionally performed to produce compensation region 250, e.g., using Arsenic at 25-45 Kev & 2.0(10¹¹)/cm²˜5.0(10¹¹)/cm². If region 250 is produced, the concentration of N-type impurity in zone 206 is increased. In FIG. 5D, a gate-dielectric second layer 204 is formed to a thickness of about 70˜80 Å, resulting in gate-dielectric parts 204c, 204b, 204a and 204y.

In FIG. 5E, floating gate layer 216 is formed, e.g., of polysilicon to a thickness of about 1000˜2000 Å. In FIG. 5F, dielectric structure 218 is formed, e.g., of an ONO structure having a lower oxide layer at a thickness of about 50 Å, a nitride layer at a thickness of about 80 Å and an upper oxide layer at thickness of about 60 Å. Then, control gate layer 220 is formed, e.g., of polysilicon to a thickness of about 1000˜2000 Å, resulting in intermediate structure.

In FIG. 5G, intermediate structure 502 is patterned and portions selectively removed to define inchoate MTR 240 and inchoate STR 242. As a result, gate-dielectric part 204y becomes gate-dielectric part 204d of inchoate MTR 240 and gate-dielectric part 204e of inchoate STR 242. Then more ion implantation is performed to produce inchoate zones 227, 228 and 231 having a lower concentration (N−) of N-type impurity, e.g., using Arsenic at 25 Kev & 2.0(10¹⁴)/cm². In FIG. 5H, sidewall spacers 252 and 254 are formed. Afterward, more ion implantation is performed to form zones 226 and 230 having a higher concentration (N+) of N-type impurity, e.g., using Arsenic at 50 Kev & 5.0(10¹⁵)/cm². Inchoate zone correspondingly gets raised to N+. Lastly, another ion implantation is performed to change zone 228 back to an N− concentration, e.g., using Phosphorous at 90 Kev & 8.0(10¹²)/cm².

The present invention being thus described, it will be obvious that the same may be varied in many ways. Such variations are not to be regarded as a departure from the spirit and scope of the present invention, and all such modifications are intended to be included within the scope of the present invention.

We claim:

1. An EEPROM cell structure having non-uniform channel-dielectric thickness, the EEPROM cell structure comprising:
a semiconductor substrate;
a memory transistor and a select transistor on the substrate; and
a floating junction formed in the substrate between the transistors and extending partially underneath the memory transistor;
a gate-dielectric layer in the memory transistor, along a lateral direction, being arranged into
a tunnel region having thickness Tₜᵤₙₙₑₗ and overlying a portion of the floating junction,
a near-channel region having thickness Tₙₑₐᵣ>Tₜᵤₙₙₑₗ and located at a side of the tunnel region opposite the select transistor, and
a far-channel region having thickness T_{far}<Tₙₑₐᵣ and located at a side of the near-channel-region opposite the tunnel-region.

2. The EEPROM cell structure of claim 1, wherein Tₜᵤₙₙₑₗ≈T_{far}.

3. The EEPROM cell structure of claim 1, wherein at least one of the following applies:
$$1 < \frac{{T}_{near}}{{T}_{tunnel}} < ( \approx 4 )$$
$$\text{and}$$
$$1 < \frac{{T}_{near}}{{T}_{far}} < ( \approx 4 ) . \\$$

4. The EEPROM cell structure of claim 1, wherein Tₙₑₐᵣ is approximately equal to a thickness of a gate-dielectric layer of the select transistor.

5. The EEPROM cell structure of claim 1, wherein a lateral dimension of the near-channel region, Lₙₑₐᵣ, is Lₙₑₐᵣ≧0.1 μm.

6. The EEPROM cell structure of claim 1, wherein the gate-dielectric in the memory transistor is further arranged to include an edge region having a thickness T_{edge}≈Tₙₑₐᵣ and located at a side of the tunnel region opposite the near-channel region.

7. The EEPROM cell structure of claim 1, wherein:
the substrate is of a first conductivity type; and
a lightly-doped compensation region of a second conductivity type is formed in the substrate underneath the far-channel-region of the gate-dielectric.

8. The EEPROM cell structure of claim 7, wherein an area of the compensation region corresponds in a self-aligned manner to the area of the far-channel-region of the gate-dielectric layer.

9. The EEPROM cell structure of claim 7, wherein:
the compensation region has a depth d_{comp}; and
a source region having a depth d_{source}>d_{comp} is formed in the substrate adjacent the compensation region.

10. The EEPROM cell structure of claim 7, wherein the conductivity type of the compensation region is N-type.

11. The EEPROM cell structure of claim 7, wherein the gate-dielectric is an oxide.

12. The EEPROM cell structure of claim 7, wherein the other dielectric is ONO.

13. The EEPROM cell structure of claim 7, wherein:
the select transistor includes a gate-dielectric layer; and
each of the transistors further includes
a polysilicon floating gate layer on the gate-dielectric layer,
another dielectric layer on the floating gate layer, and
a polysilicon control gate layer on the other dielectric layer;

14. A method of making an EEPROM cell structure having varied channel-dielectric thickness, the method comprising:
forming a gate-dielectric first layer on a semiconductor substrate having first, second and third areas corresponding later in manufacture to tunnel, far-channel and near-channel regions, respectively, the first and third areas being separated by the second area;
selectively removing portions of the first layer over the first and third areas;
forming a gate-dielectric second layer on the first layer and exposed portions of the substrate;
thicknesses Tₜᵤₙₙₑₗ, Tₙₑₐᵣ and T_{far} of gate-dielectric material over the first, second and third areas, respectively, having the relationships Tₙₑₐᵣ>Tₜᵤₙₙₑₗ and Tₙₑₐᵣ>T_{far};
forming successively, on the second layer, additional layers corresponding to components of a transistor; and
selectively removing portions of the first, second and additional layers to define inchoate memory and select transistors such that the first, second and third areas are located below the memory transistor.

15. The method of claim 14, wherein Tₜᵤₙₙₑₗ≈T_{far}.

16. The method of claim 14, wherein at least one of the following applies:
$$1 < \frac{{T}_{near}}{{T}_{tunnel}} < ( \approx 4 )$$
$$\text{and}$$
$$1 < \frac{{T}_{near}}{{T}_{far}} < ( \approx 4 ) . \\$$

17. The method of claim 14, wherein Tₙₑₐᵣ is approximately equal to the thickness of a gate-dielectric layer of the select transistor.

18. The method of claim 14, wherein a lateral dimension of the near-channel region, Lₙₑₐᵣ, is Lₙₑₐᵣ≧0.1 μm.

19. The method of claim 14, wherein the step of selectively removing portions of the first layer results in a thickness T_{edge} of gate-dielectric material over a fourth area, located at a side of the first area opposite the second area and corresponding to an edge region has the relationship T_{edge}≈Tₙₑₐᵣ.

20. The method of claim 14, wherein:
the substrate is of a first conductivity type; and
the method further comprises
forming a lightly-doped compensation region of a second conductivity type in third area of the substrate.

21. The method of claim 20, further comprising:
extending the compensation region down to a depth d_{comp}; and
forming a source region down to a depth d_{source}>d_{comp} in the substrate.

22. The method of claim 20, further comprising:
making the conductivity type of the compensation region be N-type.

23. The method of claim 14, further comprising:
using oxide as material for the gate-dielectric first and second layers.

24. An EEPROM cell structure having varied gate-dielectric thickness, the EEPROM comprising:
a semiconductor substrate;
a memory transistor and a corresponding select transistor on the substrate; and
a floating junction formed in the substrate between the transistors and extending partially underneath the memory transistor;
thickness of a portion, located over a channel region, of a gate-dielectric layer in the memory transistor being non-uniform to a degree of non-uniformity significantly greater than would result from manufacturing-tolerance associated with manufacture of a uniform-thickness layer.

25. The EEPROM cell structure of claim 24, wherein:
thickness T_{further} of the gate-dielectric layer over the channel region and disposed further from the corresponding select-transistor is less than thickness Tₗₒₛₑᵣ of the gate-dielectric layer over the channel region but disposed closer to the corresponding select-transistor, T_{further}<T_{closer}.

26. A method of making an EEPROM cell structure having varied gate-dielectric thickness, the method comprising:
forming a gate-dielectric first layer on a semiconductor substrate;
selectively removing portions of the first layer over predetermined areas of the substrate;
forming a gate-dielectric second layer on the first layer and exposed portions of the substrate;
forming successively, on the second layer, additional layers corresponding to components of a transistor; and
selectively removing portions of the first, second and additional layers to define an inchoate memory transistor and a corresponding inchoate select transistors;
thickness, located over a channel region, of gate-dielectric material in the inchoate memory-transistor is non-uniform to a degree of non-uniformity significantly greater than would result from manufacturing-tolerance associated with manufacture of a uniform-thickness layer.

27. The EEPROM cell structure of claim 26, further comprising:
selectively removing portions of the first layer such that resulting thickness T_{further}, of the gate-dielectric material over the channel region and disposed further from the corresponding select-transistor, is less than resulting thickness T_{closer} of the gate-dielectric layer over the channel region but disposed closer to the corresponding select-transistor, T_{further}<T_{closer}.
